(19) United States
(12) Patent Application Publication
(10) Pub. No.: US 2011/0038134 A1
(43) Pub. Date: Feb. 17, 2011

(54) PREVENTING OR MITIGATING GROWTH FORMATIONS ON METAL FILMS

(75) Inventor: John W. Osenbach, Kutztown, PA (US)

Correspondence Address: HITT GAINES, PC;LSI Corporation, PO BOX 832570, RICHARDSON, TX, 75083, US

(73) Assignee: AGERE SYSTEMS INC., Allentown, PA (US)

(21) Appl. No.: 12/937,389

(22) PCT Filed: Jun. 30, 2008
(86) PCT No.: PCT/US08/68705

§ 371 Date: Oct. 12, 2010

(51) Int. Cl. H05K 7/18

(52) U.S. Cl. 361/813

(57) ABSTRACT

The disclosure, in one aspect, provides an electronics package 100 comprising comprises a substrate 105 and a metal film 110 plated to a surface 107 of the substrate. The metal film has a polycrystalline structure of grains 120 having substantially anisotropic crystal unit cell dimensions. One dimension 130 of the crystal unit cells 125 are oriented in a direction 135 that is substantially perpendicular to the substrate surface for at least about 80 percent of the grains. Metal atoms of the metal film have a slower lattice diffusion coefficient along the perpendicularly-oriented unit cell dimension than along others of the unit cell dimensions 132, 134.

### CROSS-REFERENCE TO RELATED APPLICATION

This application claims the benefit of PCT Application No. PCT/US2008/068705, filed by John W. Osenbach on Jun. 30, 2008, entitled “PREVENTING OR MITIGRATING GROWTH FORMATIONS ON METAL FILMS,” commonly assigned with this application and incorporated herein by reference.

### TECHNICAL FIELD

The present invention relates generally to electronics packages, and, more particularly, to metal films used for electronic packages and their methods of manufacture.

### BACKGROUND

It is known that growth formations, commonly referred to as “whiskers,” can form on certain types of metal films used in electronics packages. For instance, surface finishes or solder connections for various components in an electronics package can spontaneously form whiskers during the operational life time of the package, and, thereby cause the package to malfunction. There is no agreed-upon mechanism by which whisker formation occurs.

Past procedures to mitigate whisker formation are not entirely satisfactory. Adding lead (Pb) to the metal film helps to prevent or mitigate whisker formation, but then there undesirable health and environment hazards associated with lead-containing packages. Thermal annealing of metal films can help reduce the rate of whisker growth, but whisker formation may still eventually occur at an unacceptable high frequency, especially for electronics packages having an extended operational lifetime (e.g., 2 years or longer, for some packages).

### SUMMARY

There is a longstanding need to prevent or mitigate whisker growth. To address the deficiencies of the prior art, the present disclosure provides in one embodiment of the disclosure, an electronics package. The electronics package comprises a substrate and a metal film plated to a surface of the substrate. The metal film has a polycrystalline structure of grains having substantially anisotropic crystal unit cell dimensions. One dimension of the crystal unit cells are oriented in a direction that is substantially perpendicular to the substrate surface for at least about 80 percent of the grains. Metal atoms of the metal film have a slower lattice diffusion coefficient along the perpendicularly-oriented unit cell dimension than along others of the unit cell dimensions.

Another embodiment of the disclosure is a method of manufacturing an electronics package. The method comprises providing a substrate and plating the above-described metal film to a surface of the substrate.

### BRIEF DESCRIPTION OF THE DRAWINGS

For a more complete understanding of the present invention, reference is now made to the following descriptions taken in conjunction with the accompanying drawings, in which:

FIG. 1A presents a perspective view of a portion of an example electronic package of the disclosure;

FIG. 1B shows a detailed view of a portion of the example electronic package of FIG. 1A;

FIG. 2 presents an illustration of critical grain size versus temperature for polycrystalline tin grains having a tetragonal, body-centered tetragonal structure and perpendicularly oriented c-axis; and

FIG. 3 presents a flow diagram illustrating selective steps in an example embodiment of manufacturing an electronics package, such as the electronics package illustrated in FIG. 1.

### DETAILED DESCRIPTION

Embodiments of the disclosure benefit from the discovery that whisker formation in certain metal films having polycrystalline structures that can be modeled and predicted based on theoretical models of creep mechanisms in metals.

While not limiting the scope of the invention by theoretical considerations, it is believed that for such polycrystalline-containing metal films, there is a critical grain size below which whisker formation does not occur, or at least, is substantially mitigated. It is also believed that this critical grain size is strongly influenced by the crystallographic orientation of grains of the metal film. In particular, the critical grain size can be increased by orienting the grain such that a unit cell dimension with the fastest lattice diffusion coefficient reduces stress formation in the grain. Embodiments of the metal film formed so that their grains have the unit cell dimension with the fastest lattice diffusion coefficient oriented substantially perpendicular to a growth surface increases the critical grain size into a range that can be avoided by appropriate manufacturing methods. By using methods to form the metal film such that its average grain size is below the critical grain size, whisker growth can thereby be prevented or mitigated.

The term grain (also commonly know as crystallites) as used herein, refers to a domain of solid-state matter that has the same structure as a single crystal of the matter.

The term whisker as used herein refers to a growth formation of grains of the metal film having a long axis length of at least about 10 microns.

The term creep as used herein refers to the solid state movement of material from a stress-induced high energy position to a lower energy position such that the system tends to its lowest energy state. It is believed that under certain conditions, whisker growth can be modeled and predicted by certain creep rate models.

The term Nabarro-Herring (NH) Creep Rate (CR) as used herein is defined by equation (1) presented below:

$$NH CR = \frac{10 Ω {D}_{l} σ}{{RT ( GS )}^{2}} \qquad ( 1 )$$

where Ω is the molar volume, Dₗ is the lattice diffusion coefficient, σ is the applied stress, R is the gas constant, T is the absolute temperature and GS is the grain size. NH creep provides a model of stress relaxation via lattice diffusion.

The term Boettinger-Huchinson-Tu (BHT) Creep Rate as used herein is defined by equation (2) presented below:

$$BHT CR = \frac{Ωδ {D}_{gb} σ}{{RTGS}_{c}^{2} ln ( \frac{c}{a} )} \qquad ( 2 )$$

where Ω, R, T and GS are the same as defined for equation (1) above, D_{gb} is the grain boundary diffusion coefficient, δ is the effective grain boundary width (note that this is a mathematical constraint that may not be the same as the “intrinsic” grain boundary thickness), c is the long range diffusion distance, and a is the radius of the whisker. BHT creep provides a model of stress relaxation via long range grain boundary diffusion and whisker growth.

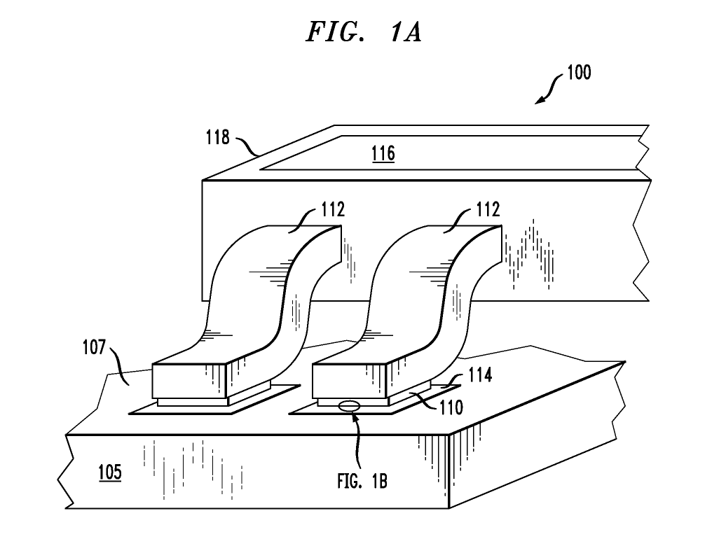

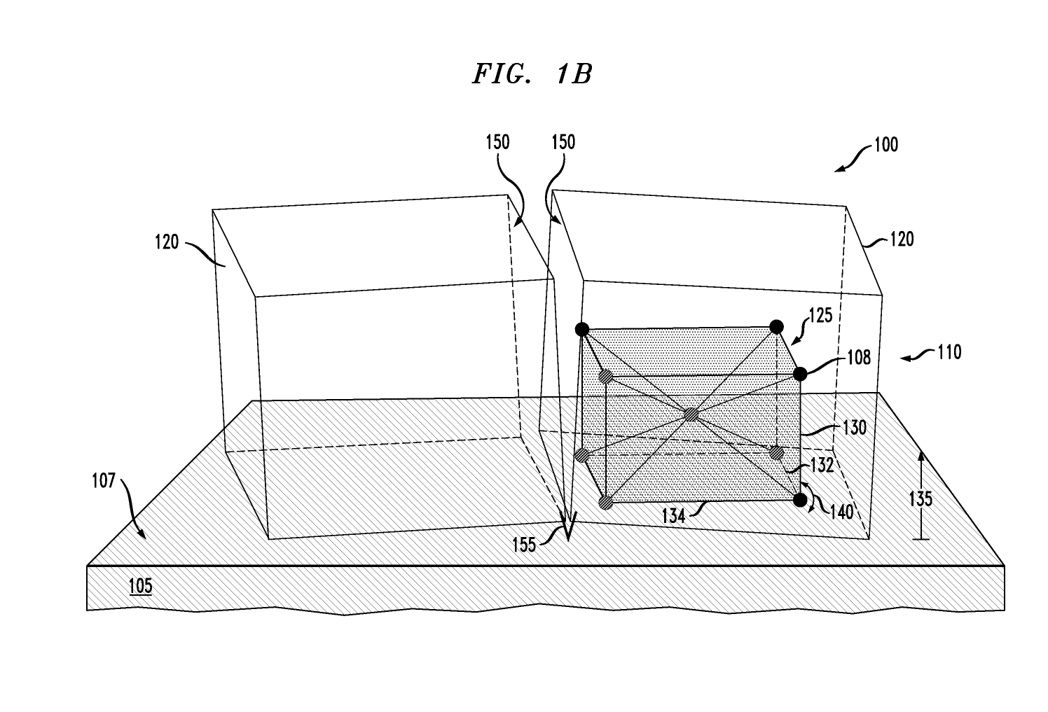

One embodiment of the disclosure is an electronics package. FIG. 1A presents a perspective view of a portion of an example electronic package 100 of the disclosure, and, FIG. 1B shows a detail view of the package 100. In some preferred embodiments the package 100 are configured as a lead frame package. Non-limiting examples include plastic dual in-line integrated circuit packages (PDIP), small outline integrated circuits (SOICs), quad flat packages (QFPs), thin QFPs (TQFPs), Small Shrink Outline Plastic packages (SSOP), thin SSOPs (TSSOPs), thin very small-outline packages (TVSOPs), or other lead-containing packages. In addition, heat sinks and a variety of different electronic socket type connectors and printed circuit boards can include packaging in accordance with the present disclosure.

The package 100 comprises a substrate 105 having a surface 107 and a metal film 110 plated to the surface 107. The substrate 105 can be any electronic component of the electronic package 100 to which the metal film 110 may be applied. For the example substrate 105 depicted in FIG. 1A, the substrate 105 can be a circuit board or lead frame of the package 100. However the term, substrate, as used herein can also refer to interconnect structures 112, landing pads 114, heat sink 116, package body 118 (e.g., an integrated circuit), or other electrical components well known to those of ordinary skill in the art.

The metal film 110 has a polycrystalline structure of grains 120. The grains 120 comprise crystal unit cells 125 having substantially anisotropic crystal unit cell dimensions 130, 132, 134. For at least about 80 percent of the grains 120 of the metal film, one dimension 130 of the crystal unit cells 125 is oriented in a direction 135 that is substantially perpendicular to the substrate surface 107. Metal atoms 108 of the metal film 110 have a faster lattice diffusion coefficient along the perpendicularly-oriented unit cell dimension 130 than along others of the unit cell dimensions 132, 134.

While not limiting the scope of the disclosure by theory, the analysis of creep mechanisms predicts that the critical grain size (GS) occurs where NH CR (equation 1) equals BHT CR (equation 2), as presented in equation (3) below:

$$GS = \frac{10 {D}_{l} {c}^{2} ln ( \frac{c}{a} )}{δ Dgb} \qquad ( 3 )$$

Whisker formation is prevented or mitigated at grain sizes equal to or less than the critical grain size given by equation (3), because stress relaxation via lattice diffusion (modeled by NH creep) becomes the primary stress relation mechanism over stress relaxation via whisker formation. Under these conditions whisker growth along the perpendicularly-oriented unit cell dimension 130 (modeled by BHT creep) is prevented or mitigated. The above-described unit cell orientation facilitates the metal film 110 having a larger critical grain size. Therefore, it is advantageous for some embodiments of the metal film 110 to have average grain sizes that are less than this critical grain size where spontaneous whisker growth would otherwise occur along the perpendicularly-oriented unit cell dimension 130.

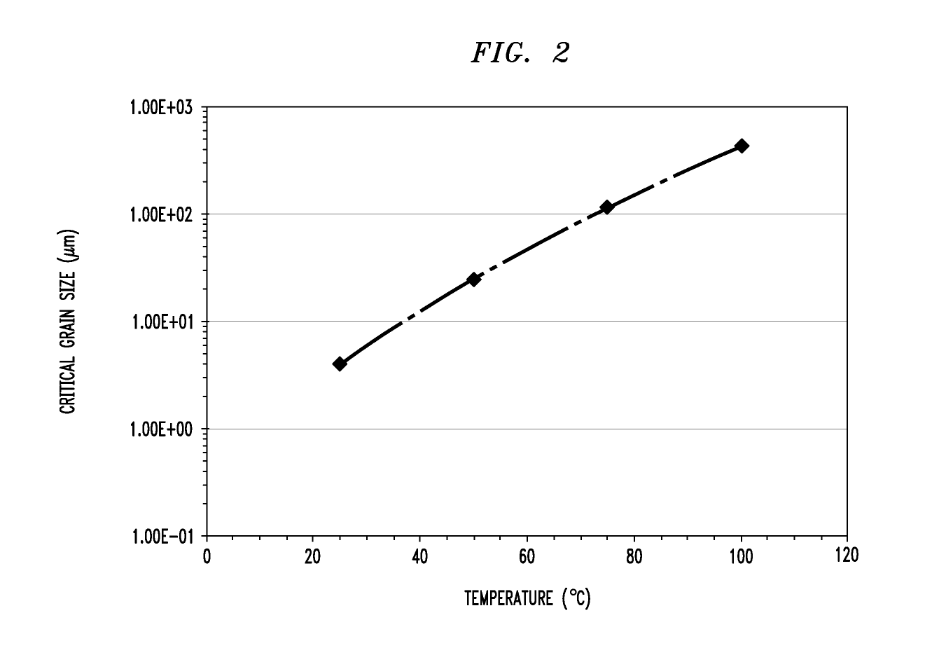

With continuing reference to FIGS. 1A and 1B, FIG. 2 shows the critical grain size predicted by equation (3) for a metal film made of tin with a body-centered tetragonal polycrystalline structure. For such a polycrystalline structure, there is one c-axis of different length, and two axes, a-axis and b-axis, having equal lengths. The perpendicularly-oriented unit cell dimension 130 corresponds to the c-axis, and the non-perpendicularly-oriented unit cell dimensions 132, 134 correspond to the a-axis and b-axis, respectively. For tetragonal materials such as tin and zinc, the c-axis is a [001] direction of the crystal unit cell, and the a-axis and b-axis correspond to [100] and [010] directions, respectively.

As illustrated in FIG. 2, the critical grain size is temperature dependent because Dₗ and D_{bg} are both defined by Arrhenius expressions (e.g., Dₗ=Dₒₗ exp (−Eₗ/RT), and, D_{bg}=D_{ogb} exp (−E_{gb}/RT)). The solid line was calculated assuming that Dₗ, D_{bg}, Eₗ and E_{gb} are equal to 0.00014 m²/sec, 0.00000644 m²/sec, 97394 J/mole, and 399000 J/mole, respectively, for the [100] and [010] directions for the non-perpendicularly-oriented unit cell dimensions 132, 134. Under these conditions, the critical grain size is predicted to be in a range of about 3 to 10 microns at metal film temperatures ranging from about 20 to 100° C.

The metal film 110 can substantially comprise metal elements that can form polycrystalline structures of grains with substantially anisotropic crystal unit cell dimensions. That is, the unit cell dimensions 130, 132, 134, are not all equal to each other, and preferably, at least one unit cell dimension 130 is at about 10 percent different in length than other unit cell dimensions 132, 134. In all cases however, the fast diffusion unit cell direction, or directions, for at least about 80% of the grains of the film are oriented perpendicular to the growth direction, e.g. the non-perpendicularly-oriented unit cell dimensions. Non-limiting examples of such metals include cadmium, indium, tin or zinc. Examples of preferred metal films 110 include at least about 85 weight percent of one or more of cadmium, indium, tin or zinc. One of ordinary skill in the art would understand how such elements form polycrystalline structures such as tetragonal, body-centered tetragonal, hexagonal, triclinic, monoclinic, or, other crystal structures with anisotropic crystal unit cell dimensions. Based upon the present disclosure, one of ordinary skill in the art would understand how to apply equations (1)-(3) to predict critical grain sizes, similar to that shown in FIG. 2, for each of these metal elements and their corresponding polycrystalline structures.

The metal film 110 can be a surface finish on the substrate 105. In some cases, the metal film 110 is an exterior plating of a conductive lead (e.g., a copper or aluminum lead). In other cases, the metal film is part of a metal container that surrounding an electronic component (e.g., an integrated circuit) to suppress electromagnetic interference to or from the enclosed component. In still other cases, the metal film 110 is a surface finish or solder that facilitates adhesion between two electronic components, e.g., a lead 112 adhered to a landing pad 114 or, a heat sink 116 adhered to a package body 118.

A faster diffusion coefficient in the non-perpendicularly-oriented unit cell dimension 130 is conducive to having a larger critical grain size. In some embodiments, the faster lattice diffusion coefficient in the non-perpendicularly-oriented unit cell dimension 130 is at least about two times faster than the lattice diffusion coefficients in the other (perpendicularly oriented) unit cell dimensions 132, 134, and more preferably, at least about four times faster.

One of ordinary skill in the art would understand how to determine whether the diffusion coefficient of the perpendicularly-oriented unit cell dimension 130 is slower than in the other dimensions 132, 134. For instance, techniques such as x-ray diffraction crystallography or electron back-scatter diffraction can be used to determine the orientation of the unit cells 125 of the grains 120. Electron microscopy techniques can, be used to determine the properties of the grains 120, such as the average grain size of the metal film 110. The diffusion coefficients in the different unit cell directions are have either been determined and are readily available in the literature, or, can be determined using conventional techniques. One technique that is widely used for determining the diffusion coefficient in the different unit cell directions is radio active isotopes of the material of interest as described in “Diffusion in Solids” P. G. Shewmon, McGraw Hill New York, 1963 and reference therein, which is incorporated by reference herein in its entirety.

An example of one way to determine that the lattice diffusion coefficient is faster in the perpendicular direction than in the parallel direction for tin is as follows. Determine the crystallographic orientation of a single crystal of Sn using x-ray spectroscopy. Place the radioactive isotope, Sn120, onto the faces of two different crystals that are oriented with Dl perpendicular to the growth direction, e.g., [100] and [010]. In another Sn crystal, apply Sn120 to the face that is oriented parallel to the growth direction [001]. Subject all three samples to a thermal anneal for a fixed period of time. Subsequently, measure the Sn120 profile from the surface where the Sn120 is applied into the bulk of the crystal. This can be accomplished by measuring the radioactive isotope concentration, then removing a known thickness of Sn crystal by polishing, and then re-measuring the isotope concentration. This process is continued until no radio active isotope is detected. The Sn120 profiles are then fit with a second order differential to determine the diffusion coefficient. In principle, the deeper the Sn120 goes into the crystal, the greater the diffusion coefficient is.

As noted above, to provide the appropriate stress relation via lattice diffusion, and hence to facilitate having the larger critical grain size, e.g., in Sn, it is desirable for the unit cell dimension 130 with the slowest lattice diffusion coefficient to be substantially perpendicularly-oriented. In some embodiments, the unit cell dimension 130 has an average angle 140 (FIG. 1B) with respect to the substrate surface 107 that is in a range from about 65 to 115 degrees, and more preferably about 90 degrees.

To decrease D_{gb}, and thereby facilitate having the larger critical grain size, it is also desirable for adjacent ones of the grains 120 to form grain boundaries 150 having a tilt angle 155 of about 20 degrees of less, and more preferably less than 5 degrees (FIG. 1B). The term grain boundary 150, as used herein refers to the outer perimeter of a grain 120 that separates it from adjacent grains 120. The term grain boundary tilt angle 155 as used herein refers to the angle formed between two opposing grain boundaries 150 of adjacent grains 120.

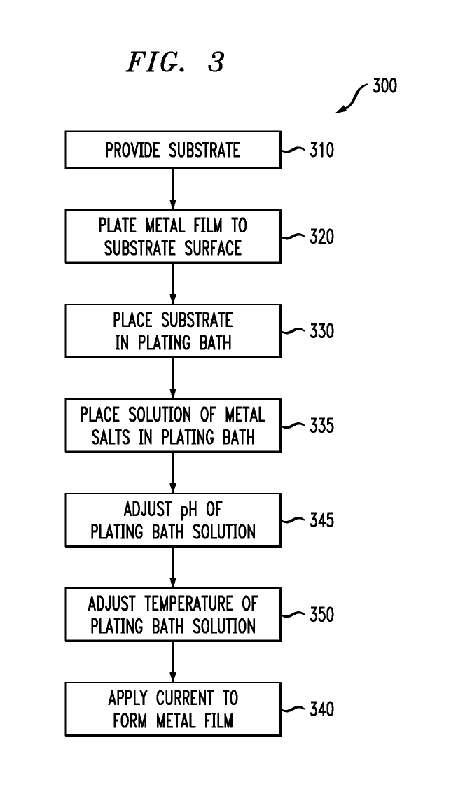

Another embodiment of the disclosure is a method of manufacturing an electronics package. FIG. 3 presents a flow diagram illustrating selective steps in an example embodiment of a method 300 of manufacturing an electronics package. Any embodiments of the example electronics package 100 illustrated in FIGS. 1A-1B can be manufactured by the method 300.

The method comprises providing a substrate in step 310 and plating a metal film to a surface of the substrate in step 320. The metal film is plated in step 320 so as to promote the characteristics that prevent or mitigate whisker growth.

The composition of the metal film (e.g., cadmium, indium, tin or zinc) is selected so as have a polycrystalline structure of grains having substantially anisotropic crystal unit cell dimensions. The metal film is plated so that one dimension of the crystal unit cell is oriented in a direction that is substantially perpendicular to the substrate surface for at least about 80 percent of the grains. The metal atoms of the metal film have a slower lattice diffusion coefficient along the perpendicularly-oriented unit cell dimension than along others of the unit cell dimensions.

In some preferred embodiments, plating in step 320 is configured to provide grains having an average size that is less than a critical grain size where spontaneous whisker growth occurs along the perpendicularly-oriented unit cell dimension.

The plating step 320 is carefully controlled to facilitate the formation of a metal film whose average grain size is less than the critical grain size. In particular, it is desirable to select conditions where the rate of formation of the metal film is slow because this is conducive to the formation of highly oriented grains. Further adjustments to the pH of the plating solution as well as the plating temperature can be used in encourage the growth of highly oriented grains. This is in contrast to conventional methods which generally are directed to plate a metal film as quickly as possible so as to minimize manufacture time.

Some embodiments the plating (step 320) include placing the substrate in an electrolytic plating bath (step 330), adding a solution comprising a metal salt of the desired metal film (e.g., a metal salt of cadmium, indium, tin or zinc, such as tin sulfamate or other metal sulfamates) to the plating bath (step 335) and applying a current to form the metal film on the substrate surface (step 340).

In some case, the metal salt solution added to the bath in step 335 includes or is an aqueous solution of a metal salt having a pre-plating initial concentration in a range from about 0.1 to 50 weight percent. In some cases, the current applied in step 340 is maintained at a current density in a range from about 0.0001 to 100 A/m². In some cases, in step 345, the aqueous solution of the electrolytic plating bath is adjusted to, and maintained at, a pH is a range from about 3 to 11 throughout the plating step 320. In some cases, the temperature of the electrolytic plating bath is adjusted (step 350) to a temperature in a range from about 10 to 100° C. The growth rate and crystallographic orientation of the grains as well as the grain sizes are determined by the combination of pH, temperature and plating current. By carefully setting the three plating parameters, the film with required grain size and orientation can be created.

Although the present invention has been described in detail, those skilled in the art should understand that they can make various changes, substitutions and alterations herein without departing from the spirit and scope of the invention in its broadest form.

What is claimed is:

1. An electronics package, comprising:
a substrate; and
a metal film plated to a surface of said substrate wherein,
said metal film has a polycrystalline structure of grains having substantially anisotropic crystal unit cell dimensions,
one dimension of said crystal unit cells are oriented in a direction that is substantially perpendicular to said substrate surface for at least about 80 percent of said grains, and
metal atoms of said metal film have a slower lattice diffusion coefficient along said perpendicularly-oriented unit cell dimension than along others of said unit cell dimensions.

2. The package of claim 1, wherein an average grain size of said grain is less than a critical grain size where spontaneous whisker growth occurs along said perpendicularly-oriented unit cell dimension.

3. The package of claim 2, wherein said metal film substantially comprises tin, said critical grain size in is a range of about 3 to 10 microns at metal film temperatures ranging from about 20 to 100° C.

4. The package of claim 1, wherein said metal film include at least about 85 weight percent of one or more of cadmium, indium, tin or zinc.

5. The package of claim 1, wherein said polycrystalline structure is one of a tetragonal, body-centered tetragonal, hexagonal, triclinic, monoclinic crystal structure.

6. The package of claim 1, wherein said slower lattice diffusion coefficient is at least about two times lower than lattice diffusion coefficients in said other unit cell dimensions.

7. The package of claim 1, wherein for said grains, said substantially perpendicularly-oriented unit cell dimension has an average angle with respect to said substrate surface that is in a range from about 65 to 115 degrees.

8. The package of claim 1, wherein said metal film substantially comprises tin, said polycrystalline structure is a body-centered tetragonal crystal structure, said other unit cell dimensions include two a-axis and b-axis of equal length and one c-axis of different length, and said perpendicularly-oriented unit cell dimension corresponding to said c-axis.

9. The package of claim 8, wherein said c-axis is a [001] direction of said crystal unit cell.

10. The package of claim 1, wherein adjacent ones of said grains form a grain boundary tilt angle of about 20 degrees of less.

11. The package of claim 1, wherein said substrate is an electronic component of said package.

12. The package of claim 1, wherein said electronic package is configured as a lead frame package.

13. A method of manufacturing an electronics package, comprising:
providing a substrate; and
plating a metal film to a surface of said substrate, wherein,
said metal film has a polycrystalline structure of grains having substantially anisotropic crystal unit cell dimensions,
one dimension of said crystal unit cell is oriented in a direction that is substantially perpendicular to said substrate surface for at least about 80 percent of said grains, and
metal atoms of said metal film have a slower lattice diffusion coefficient along said perpendicularly-oriented unit cell dimension than along others of said unit cell dimensions.

14. The method of claim 13, wherein said plating is configured to provide said grains having an average size that is less than a critical grain size where spontaneous whisker growth occurs along said perpendicularly-oriented unit cell dimension.

15. The method of claim 14, wherein said plating includes placing said substrate in an electrolytic plating bath adding a solution comprising a metal salt of said metal film to said plating bath, and applying a current to form said metal film on said substrate surface.

16. The method of claim 15, wherein said metal salt includes tin sulfamate.

17. The method of claim 14, wherein said applied current is maintained at a current density in a range from about 0.0001 to 100 A/m².

18. The method of claim 14, wherein said electrolytic plating solution is adjusted to a pH is a range from about 3 to 11.

19. The method of claim 14, wherein said electrolytic plating bath is adjusted to a temperature in a range from about 10 to 100° C.

20. The method of claim 14, wherein said metal salt has a pre-plating initial concentration in a range from about 0.1 to 50 weight percent.
